(19) United States
(12) Patent Application Publication
(10) Pub. No.: US 2018/0266910 A1
(43) Pub. Date: Sep. 20, 2018

(54) PRESSURE SENSOR, PRESSURE SENSOR MODULE, ELECTRONIC APPARATUS, AND VEHICLE

(71) Applicant: SEIKO EPSON CORPORATION, Tokyo (JP)

(72) Inventors: Yusuke MATSUZAWA, Chino-shi (JP); Nobuyuki TANAKA, Chino-shi (JP)

(73) Assignee: SEIKO EPSON CORPORATION, Tokyo (JP)

(21) Appl. No.: 15/914,067

(22) Filed: Mar. 7, 2018

(30) Foreign Application Priority Data
Mar. 14, 2017 (JP) 2017-048847

(51) Int. Cl. G01L 19/04; B81B 3/00; B81B 7/00

(52) U.S. Cl. CPC G01L 19/04; B81B 3/0072; G01L 9/0052; B81B 2201/0264; B81B 2203/0127; B81B 7/0038

(57) ABSTRACT

A pressure sensor includes a substrate which has a diaphragm that is flexurally deformed by receiving a pressure, a side wall section which is placed on one surface side of the substrate and surrounds the diaphragm in a plan view, and a sealing layer which is placed so as to face the diaphragm through a space and seals the space, wherein the sealing layer includes a first silicon layer which has a through-hole facing the space, a silicon oxide layer which is located on the opposite side to the space with respect to the first silicon layer and seals the through-hole, and a second silicon layer which is located on the opposite side to the space with respect to the silicon oxide layer.

### BACKGROUND

### 1. Technical Field

The present invention relates to a pressure sensor, a production method for a pressure sensor, a pressure sensor module, an electronic apparatus, and a vehicle.

### 2. Related Art

There has been known a configuration described in JP-A-2015-184100 (Patent Document 1) as a pressure sensor. The pressure sensor described in Patent Document 1 includes a substrate having a diaphragm which is flexurally deformed by receiving a pressure and a surrounding structure placed on the substrate, and a pressure reference chamber is formed therebetween. Further, the surrounding structure includes a frame-shaped wall section surrounding the pressure reference chamber and a ceiling section covering an opening of the wall section. Further, the ceiling section includes a coating layer having a through-hole for release etching, and a sealing layer which is stacked on the coating layer and seals the through-hole.

In the pressure sensor having such a configuration, the sealing layer is constituted by a metal material (a material having a large thermal expansion coefficient) such as Al or Ti. Therefore, due to the expansion of the sealing layer, the internal stress of the diaphragm greatly changes depending on the environmental temperature. Due to this, even if the same pressure is received, the measured value varies depending on the environmental temperature, and the pressure detection accuracy may be deteriorated.

### SUMMARY

An advantage of some aspects of the invention is to provide a pressure sensor capable of exhibiting excellent pressure detection accuracy, a production method for the pressure sensor, a pressure sensor module, an electronic apparatus, and a vehicle.

The advantage can be achieved by the following configurations.

A pressure sensor according to an aspect of the invention includes a substrate which has a diaphragm that is flexurally deformed by receiving a pressure, a side wall section which is placed on one surface side of the substrate and surrounds the diaphragm in a plan view, and a sealing layer which is placed so as to face the diaphragm through a space and seals the space, wherein the sealing layer includes a first silicon layer which has a through-hole facing the space, a silicon oxide layer which is located on the opposite side to the space with respect to the first silicon layer and seals the through-hole, and a second silicon layer which is located on the opposite side to the space with respect to the silicon oxide layer.

In this manner, by placing the through-hole in the first silicon layer, the sealing layer is easily deformed in the in-plane direction. Therefore, the internal stress of the pressure sensor is relaxed by the sealing layer, and the internal stress is less likely to be transmitted to the diaphragm. Accordingly, the change in the internal stress applied to the diaphragm depending on the environmental temperature can be suppressed, and the pressure sensor capable of exhibiting excellent pressure detection accuracy is formed.

In the pressure sensor according to the aspect of the invention, it is preferred that the transverse cross-sectional area of the through-hole gradually decreases from the space side to the silicon oxide layer side.

According to this configuration, the space in the through-hole can be sufficiently ensured, and therefore, the through-hole can be more easily deformed, and also the opening of the through-hole on the silicon oxide layer side can be sufficiently decreased. Due to this, the sealing layer can be more easily deformed in the in-plane direction, and also the through-hole can be more reliably closed with the silicon oxide layer.

In the pressure sensor according to the aspect of the invention, it is preferred that the through-hole has a portion in which the changing ratio of the transverse cross-sectional area gradually decreases from the space side to the silicon oxide layer side.

According to this configuration, the change in the transverse cross-sectional area on the silicon oxide layer side of the through-hole becomes gradual, and therefore, it becomes easy to control the size of the diameter of the opening on the silicon oxide layer side.

In the pressure sensor according to the aspect of the invention, it is preferred that the first silicon layer is placed so as to surround the opening of the through-hole, and has a protrusion portion which protrudes to the space side.

According to this configuration, even if the sealing layer is flexed on the diaphragm side and comes into contact with the diaphragm, the contact area between these members can be suppressed small, and the occurrence of “sticking” in which the sealing layer sticks to the diaphragm while being in contact therewith can be effectively suppressed.

In the pressure sensor according to the aspect of the invention, it is preferred that the silicon oxide layer is sealed from the outside by being covered with the second silicon layer.

According to this configuration, the silicon oxide layer can be protected from water, and the change in the internal stress of the sealing layer depending on the environmental humidity can be suppressed.

In the pressure sensor according to the aspect of the invention, it is preferred that the first silicon layer is thicker than the second silicon layer and the silicon oxide layer.

Since the through-hole is placed in the first silicon layer, the mechanical strength is more likely to decrease than the other layers (the silicon oxide layer and the second silicon layer). Therefore, by satisfying such a relationship, a sufficient mechanical strength can be imparted to the first silicon layer.

In the pressure sensor according to the aspect of the invention, it is preferred that the substrate contains silicon.

According to this configuration, handling in production is facilitated, and excellent processing dimensional accuracy can be exhibited.

A production method for a pressure sensor according to an aspect of the invention includes preparing a substrate which has a diaphragm forming region, placing a sacrificial layer on one surface side of the substrate so as to overlap with the diaphragm forming region in a plan view, placing a first silicon layer which has a through-hole facing the sacrificial layer on the opposite side to the substrate with respect to the sacrificial layer, removing at least a part of the sacrificial layer through the through-hole, placing a silicon oxide layer on the opposite side to the substrate with respect to the first silicon layer so as seal the through-hole, placing a second silicon layer on the opposite side to the substrate with respect to the silicon oxide layer, and forming a diaphragm which is flexurally deformed by receiving a pressure in the diaphragm forming region of the substrate.

According to this configuration, the sealing layer which is easily deformed in the in-plane direction is obtained. Therefore, the internal stress of the pressure sensor is relaxed by the sealing layer, and the internal stress is less likely to be transmitted to the diaphragm. Accordingly, the change in the internal stress applied to the diaphragm depending on the environmental temperature can be suppressed, and the pressure sensor capable of exhibiting excellent pressure detection accuracy is obtained.

A pressure sensor module according to an aspect of the invention includes the pressure sensor according to the aspect of the invention and a package which houses the pressure sensor.

According to this configuration, the effect of the pressure sensor according to the aspect of the invention can be received, and therefore, a pressure sensor module having high reliability is obtained.

An electronic apparatus according to an aspect of the invention includes the pressure sensor according to the aspect of the invention.

According to this configuration, the effect of the pressure sensor according to the aspect of the invention can be received, and therefore, an electronic apparatus having high reliability is obtained.

A vehicle according to an aspect of the invention includes the pressure sensor according to the aspect of the invention.

According to this configuration, the effect of the pressure sensor according to the aspect of the invention can be received, and therefore, a vehicle having high reliability is obtained.

### BRIEF DESCRIPTION OF THE DRAWINGS

The invention will be described with reference to the accompanying drawings, wherein like numbers reference like elements.

FIG. 1 is a cross-sectional view showing a pressure sensor according to a first embodiment of the invention.

FIG. 2 is a plan view showing a sensor section included in the pressure sensor shown in FIG. 1.

FIG. 3 is a view showing a bridge circuit including the sensor section shown in FIG. 2.

FIG. 4 is an enlarged cross-sectional view showing a sealing layer included in the pressure sensor shown in FIG. 1.

FIG. 5 is a flowchart showing a production step of the pressure sensor shown in FIG. 1.

FIG. 6 is a cross-sectional view for illustrating a production method for the pressure sensor shown in FIG. 1.

FIG. 7 is a cross-sectional view for illustrating the production method for the pressure sensor shown in FIG. 1.

FIG. 8 is a cross-sectional view for illustrating the production method for the pressure sensor shown in FIG. 1.

FIG. 9 is a cross-sectional view for illustrating the production method for the pressure sensor shown in FIG. 1.

FIG. 10 is a cross-sectional view for illustrating the production method for the pressure sensor shown in FIG. 1.

FIG. 11 is a cross-sectional view for illustrating the production method for the pressure sensor shown in FIG. 1.

FIG. 12 is a cross-sectional view for illustrating the production method for the pressure sensor shown in FIG. 1.

FIG. 13 is a cross-sectional view for illustrating the production method for the pressure sensor shown in FIG. 1.

FIG. 14 is a cross-sectional view for illustrating the production method for the pressure sensor shown in FIG. 1.

FIG. 15 is a cross-sectional view for illustrating the production method for the pressure sensor shown in FIG. 1.

FIG. 16 is a cross-sectional view for illustrating the production method for the pressure sensor shown in FIG. 1.

FIG. 17 is a cross-sectional view showing a pressure sensor according to a second embodiment of the invention.

FIG. 18 is a cross-sectional view for illustrating a production method for the pressure sensor shown in FIG. 17.

FIG. 19 is a cross-sectional view for illustrating the production method for the pressure sensor shown in FIG. 17.

FIG. 20 is a cross-sectional view for illustrating the production method for the pressure sensor shown in FIG. 17.

FIG. 21 is a cross-sectional view for illustrating the production method for the pressure sensor shown in FIG. 17.

FIG. 22 is a cross-sectional view showing a pressure sensor module according to a third embodiment of the invention.

FIG. 23 is a plan view of a support substrate included in the pressure sensor module shown in FIG. 22.

FIG. 24 is a perspective view showing an altimeter as an electronic apparatus according to a fourth embodiment of the invention.

FIG. 25 is a front view showing a navigation system as an electronic apparatus according to a fifth embodiment of the invention.

FIG. 26 is a perspective view showing a car as a vehicle according to a sixth embodiment of the invention.

### DESCRIPTION OF EXEMPLARY EMBODIMENTS

Hereinafter, a pressure sensor, a production method for a pressure sensor, a pressure sensor module, an electronic apparatus, and a vehicle according to the invention will be described in detail based on embodiments shown in the accompanying drawings.

### First Embodiment

First, a pressure sensor according to a first embodiment of the invention will be described.

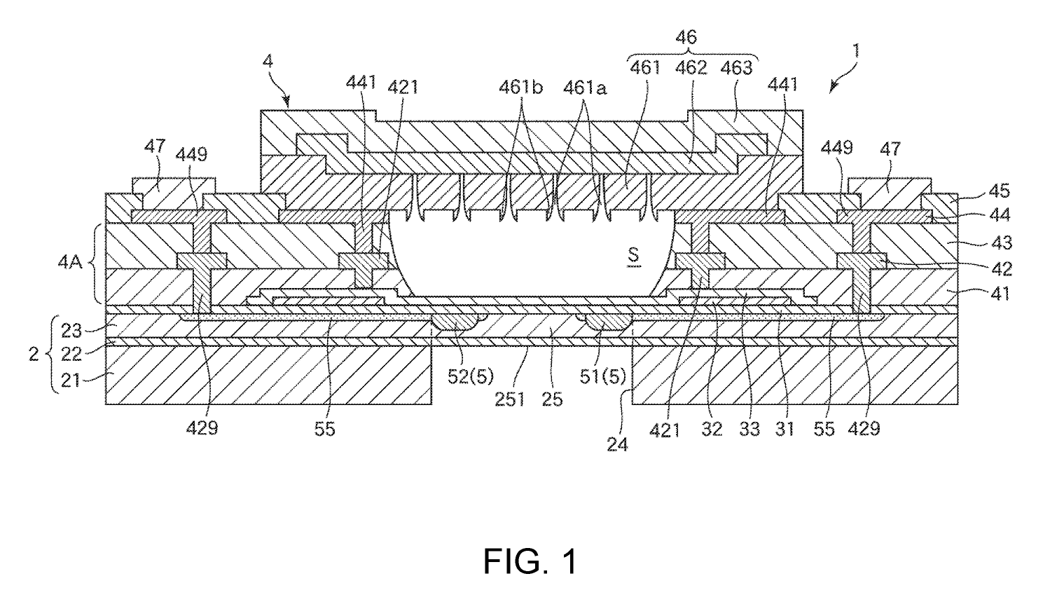

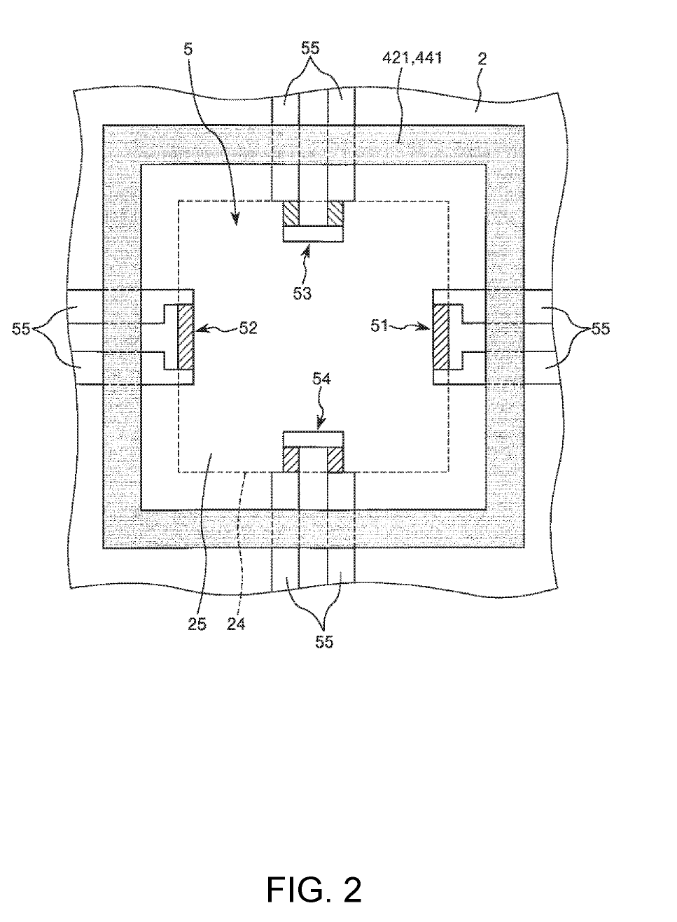

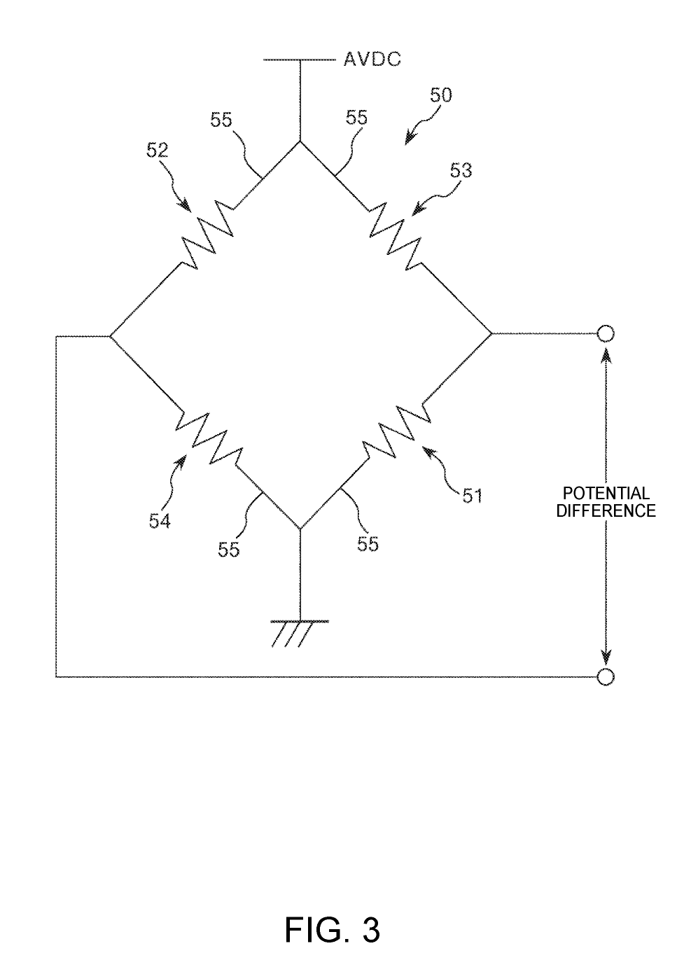

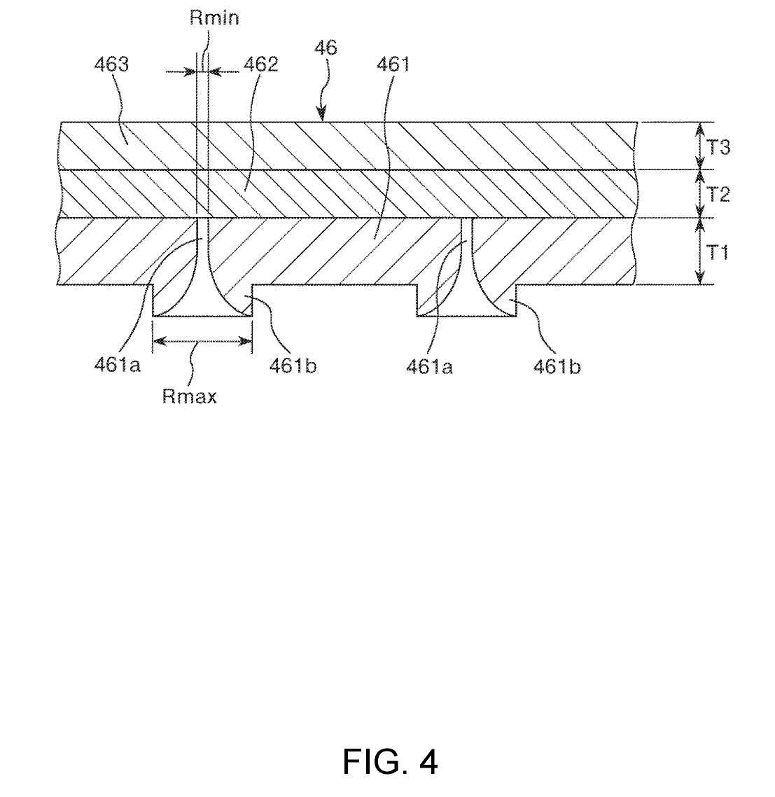

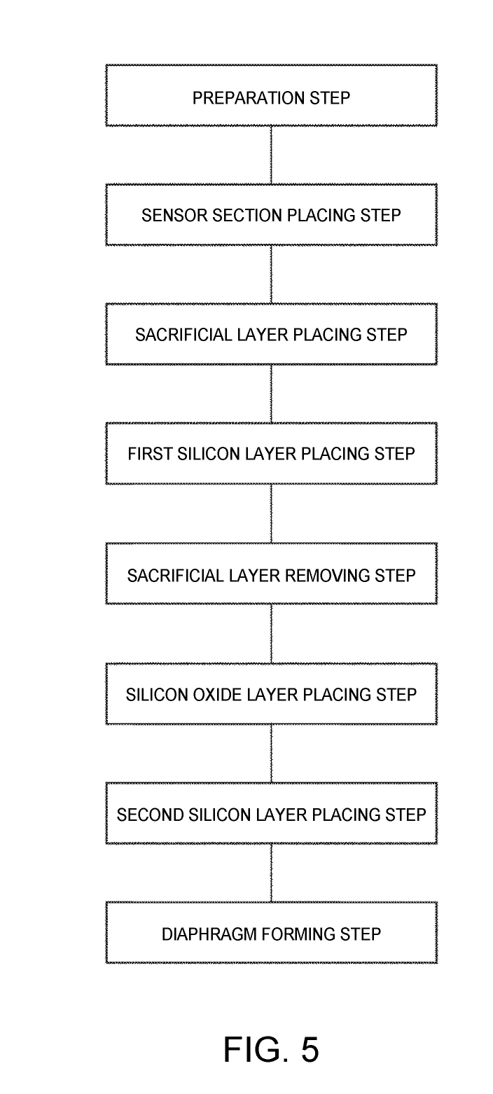

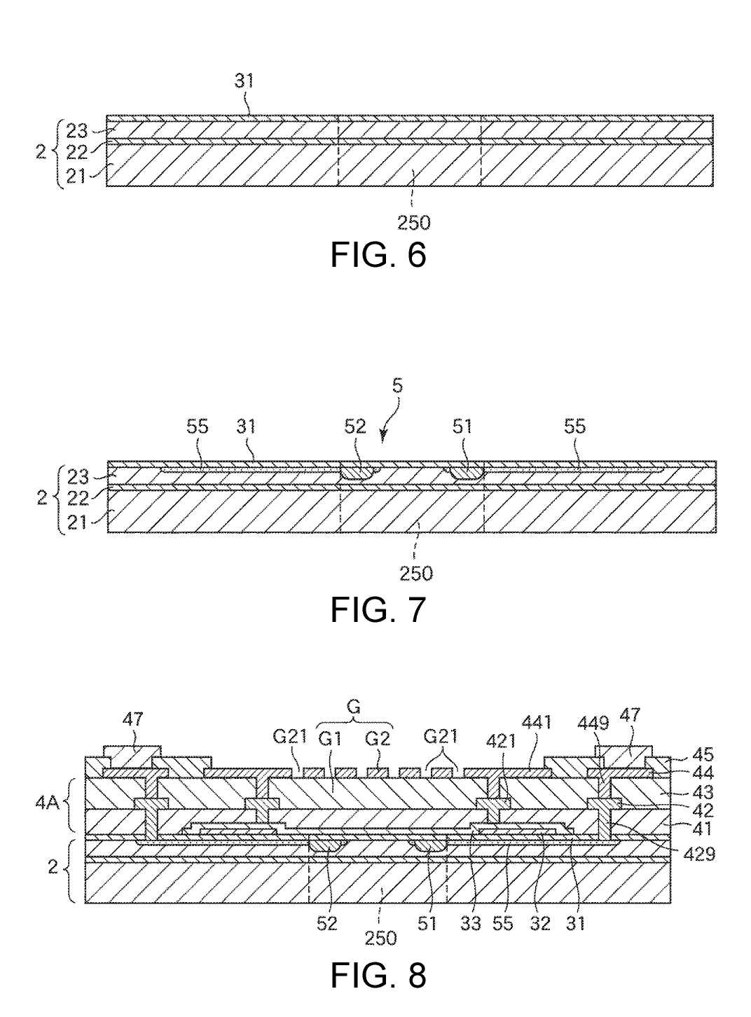

FIG. 1 is a cross-sectional view showing the pressure sensor according to the first embodiment of the invention. FIG. 2 is a plan view showing a sensor section included in the pressure sensor shown in FIG. 1. FIG. 3 is a view showing a bridge circuit including the sensor section shown in FIG. 2. FIG. 4 is an enlarged cross-sectional view showing a sealing layer included in the pressure sensor shown in FIG. 1. FIG. 5 is a flowchart showing a production step of the pressure sensor shown in FIG. 1. FIGS. 6 to 16 are each a cross-sectional view for illustrating a production method for the pressure sensor shown in FIG. 1. In the following description, in each of FIGS. 1, 4, and 6 to 16, the upper side and the lower side are also referred to as “upper” and “lower”, respectively. Further, a plan view of a substrate, that is, a plan view viewed from the vertical direction in FIG. 1 is also simply referred to as “a plan view”.

As shown in FIG. 1, a pressure sensor 1 includes a substrate 2 which has a diaphragm 25 that is flexurally deformed by receiving a pressure, a pressure reference chamber S (cavity section) which is placed on the upper surface side of the diaphragm 25, a surrounding structure 4 which forms the pressure reference chamber S along with the substrate 2, and a sensor section 5 which is placed on the diaphragm 25.

As shown in FIG. 1, the substrate 2 is constituted by an SOI substrate including a first layer 21 which is constituted by silicon, a third layer 23 which is placed on the upper side of the first layer 21 and is constituted by silicon, and a second layer 22 which is placed between the first layer 21 and the third layer 23 and is constituted by silicon oxide. That is, the substrate 2 contains silicon (Si). According to this, handling in production is facilitated, and excellent processing dimensional accuracy can be exhibited. However, the substrate 2 is not limited to the SOI substrate, and for example, a single-layer silicon substrate can also be used. The substrate 2 may be a substrate (semiconductor substrate) constituted by a semiconductor material other than silicon, for example, germanium, gallium arsenide, gallium arsenide phosphide, gallium nitride, silicon carbide, or the like.

Further, as shown in FIG. 1, in the substrate 2, a diaphragm 25 which is thinner than the peripheral portion and is flexurally deformed by receiving a pressure is provided. In the substrate 2, a bottomed recessed section 24 which opens downward is formed, and a portion where the substrate 2 is thinned due to this recessed section 24 becomes the diaphragm 25. Further, the lower surface of the diaphragm 25 becomes a pressure receiving surface 251 which receives a pressure. In this embodiment, the plan view shape of the diaphragm 25 is an approximate square, however, the plan view shape of the diaphragm 25 is not particularly limited, and for example, may have four chamfered corners or may be a circle.

Here, in this embodiment, the recessed section 24 is formed by dry etching using a silicon deep etching device. Specifically, the recessed section 24 is formed by repeating the step of isotropic etching, protective film formation, and anisotropic etching from the lower surface side of the substrate 2 so as to dig the first layer 21. When etching reaches the second layer 22 by repeating this step, the second layer 22 serves as an etching stopper and the etching is terminated, whereby the recessed section 24 is obtained. According to such a forming method, the inner wall side surface of the recessed section 24 is substantially perpendicular to the main surface of the substrate 2, and therefore, the opening area of the recessed section 24 can be made small. Therefore, a decrease in the mechanical strength of the substrate 2 can be suppressed, and also an increase in the size of the pressure sensor 1 can be suppressed.

However, the forming method for the recessed section 24 is not limited to the above-mentioned method, and the recessed section 24 may be formed by, for example, wet etching. Further, in this embodiment, the second layer 22 remains on the lower surface side of the diaphragm 25, however, this second layer 22 may be removed. That is, the diaphragm 25 may be constituted by a single layer of the third layer 23. According to this, the diaphragm 25 can be made thinner, and thus, the diaphragm 25 which is more easily flexurally deformed is obtained. Further, the recessed section 24 may be formed to the middle of the first layer 21.

The thickness of the diaphragm 25 is not particularly limited and varies also depending on the size or the like of the diaphragm 25, however, for example, in a case where the width of the diaphragm 25 is 100 μm or more and 300 μm or less, the thickness thereof is preferably 1 μm or more and 10 μm or less, more preferably 1 μm or more and 3 μm or less. By setting the thickness within such a range, the diaphragm 25 which is sufficiently thin and is more easily flexurally deformed by receiving a pressure while sufficiently maintaining the mechanical strength is obtained.

In the diaphragm 25, the sensor section 5 capable of detecting a pressure to act on the diaphragm 25 is provided. As shown in FIG. 2, the sensor section 5 includes four piezoresistive elements 51, 52, 53, and 54 provided in the diaphragm 25. The piezoresistive elements 51, 52, 53, and 54 are electrically connected to one another through a wiring 55 and constitute abridge circuit 50 (Wheatstone bridge circuit) shown in FIG. 3. To the bridge circuit 50, a drive circuit which supplies (applies) a drive voltage AVDC is connected. Then, the bridge circuit 50 outputs a detection signal (voltage) in accordance with the change in the resistance value of the piezoresistive element 51, 52, 53, or 54 based on the flexure of the diaphragm 25. Due to this, a pressure received by the diaphragm 25 can be detected based on this output detection signal.

In particular, the piezoresistive elements 51, 52, 53, and 54 are placed in an outer edge portion of the diaphragm 25. When the diaphragm. 25 is flexurally deformed by receiving a pressure, a large stress is applied particularly to the outer edge portion in the diaphragm 25, and therefore, by placing the piezoresistive elements 51, 52, 53, and 54 in the outer edge portion, the above-mentioned detection signal can be increased, and thus, the pressure detection sensitivity is improved. The placement of the piezoresistive elements 51, 52, 53, and 54 is not particularly limited, and for example, the piezoresistive elements 51, 52, 53, and 54 may be placed across the outer edge of the diaphragm 25.

Each of the piezoresistive elements 51, 52, 53, and 54 is formed by, for example, doping (diffusing or injecting) an impurity such as phosphorus or boron into the third layer 23 of the substrate 2. The wiring 55 is formed by, for example, doping (diffusing or injecting) an impurity such as phosphorus or boron into the third layer 23 of the substrate 2 at a higher concentration than in the piezoresistive elements 51, 52, 53, and 54.

The configuration of the sensor section 5 is not particularly limited as long as it can detect a pressure received by the diaphragm 25. For example, a configuration in which at least one piezoresistive element which does not constitute the bridge circuit 50 is placed in the diaphragm 25 may be adopted. Further, as the sensor section, an electrostatic capacitance type which detects a pressure based on a change in electrostatic capacitance may be used other than the piezoresistive type as in this embodiment.

Further, as shown in FIG. 1, on the upper surface of the substrate 2, a first insulating film 31 composed of a silicon oxide film (SiO₂ film) is formed. By such a first insulating film 31, the interface states of the piezoresistive elements 51, 52, 53, and 54 are reduced, and the occurrence of noise can be suppressed.

Further, on the first insulating film 31, a second insulating film 32 which has a frame shape surrounding the periphery of the diaphragm 25 so as not to overlap with the diaphragm 25 and is composed of a silicon nitride film (SiN film) is formed. Further, on the first insulating film 31 and the second insulating film 32, a conductive film 33 composed of polysilicon (p-Si) is formed. By the second insulating film 32 and the conductive film 33, the sensor section 5 can be protected from water, gases, etc. In this embodiment, the second insulating film 32 is placed so as not to overlap with the diaphragm 25, and the conductive film 33 is placed so as not to overlap with the diaphragm 25. This is because the conductive film 33 can be formed thinner than the second insulating film 32, and the substantial thickness of the diaphragm 25 (the thickness obtained by adding the thickness of the first insulating film 31 and the thickness of the conductive film 33 to the thickness of the diaphragm 25) can be made thinner.

The conductive film 33 functions as an etching stopper when a sacrificial layer G which fills the pressure reference chamber S is removed by etching as described in the below-mentioned production method. According to this, the first insulating film 31 and the sensor section 5 can be protected. Further, for example, by setting the conductive film 33 to a reference potential (ground potential) or by applying the drive voltage of the sensor section 5 to the conductive film 33, the conductive film 33 can be made to function as a shield layer which protects the sensor section 5 from disturbance. Due to this, the sensor section 5 is less likely to be affected by disturbance, and therefore, the pressure detection accuracy of the pressure sensor 1 can be further enhanced.

At least one of the first insulating film 31, the second insulating film 32, and the conductive film 33 may be omitted or may be constituted by a different material.

Further, as shown in FIG. 1, on the upper side of the diaphragm 25, the pressure reference chamber S is provided. This pressure reference chamber S is formed by being surrounded by the substrate 2 and the surrounding structure 4. The pressure reference chamber S is a hermetically sealed space, and the pressure in the pressure reference chamber S becomes the reference value of a pressure to be detected by the pressure sensor 1. In particular, the pressure reference chamber S is preferably in a vacuum state (for example, about 10 Pa or less). According to this, the pressure sensor 1 can be used as an “absolute pressure sensor” which detects a pressure with reference to vacuum, and the pressure sensor 1 with high convenience is formed. However, the pressure reference chamber S may not be in a vacuum state as long as the pressure therein is kept constant.

The surrounding structure 4 forms the pressure reference chamber S between the surrounding structure 4 and the substrate 2. Such a surrounding structure 4 includes an interlayer insulating film 41 placed on the substrate 2, a wiring layer 42 placed on the interlayer insulating film 41, an interlayer insulating film 43 placed on the wiring layer 42 and the interlayer insulating film 41, a wiring layer 44 placed on the interlayer insulating film 43, a surface protective film 45 placed on the wiring layer 44 and the interlayer insulating film 43, a sealing layer 46 placed on the wiring layer 44 and the surface protective film 45, and a terminal 47 placed on the surface protective film 45.

The interlayer insulating films 41 and 43 each have a frame shape and are placed so as to surround the diaphragm 25 in a plan view. By these interlayer insulating films 41 and 43, a side wall section 4A is constituted. Further, in the inside of the side wall section 4A, a space (that is, the pressure reference chamber S) is formed.

The wiring layer 42 includes a frame-shaped guard ring 421 placed so as to surround the pressure reference chamber S and a wiring section 429 connected to the wiring 55 of the sensor section 5. The wiring layer 44 includes a frame-shaped guard ring 441 placed so as to surround the pressure reference chamber S and a wiring section 449 connected to the wiring 55.

The surface protective film 45 has a function of protecting the surrounding structure 4 from water, gases, dust, scratches, etc. The surface protective film 45 is placed on the interlayer insulating film 43 and the wiring layer 44. Further, on the surface protective film 45, a plurality of terminals 47 electrically connected to the sensor section 5 through the wiring sections 429 and 449 are provided.

The sealing layer 46 is located on the ceiling of the pressure reference chamber S (an upper end face of the space formed inside the side wall section 4A) and is placed so as to cover the pressure reference chamber S formed inside the side wall section 4A. By this sealing layer 46, the pressure reference chamber S is sealed.

In such a surrounding structure 4, as the interlayer insulating films 41 and 43, for example, an insulating film such as a silicon oxide film (SiO₂ film) can be used. Further, as the wiring layers 42 and 44 and the terminal 47, for example, a metal film such as an aluminum film can be used. Further, as the surface protective film 45, for example, a silicon oxide film, a silicon nitride film, a polyimide film, an epoxy resin film, or the like can be used.

Next, the sealing layer 46 will be described in detail. As shown in FIG. 1, the sealing layer 46 has a three-layer structure including a first silicon layer 461 having a lower surface facing the pressure reference chamber S, a silicon oxide layer 462 stacked on the upper surface of the first silicon layer 461, and a second silicon layer 463 stacked on the upper surface of the silicon oxide layer 462. By forming the sealing layer 46 into a stacked structure in this manner, the pressure reference chamber S can be more reliably sealed airtightly. The configuration of the sealing layer 46 is not particularly limited, and for example, another layer may be interposed between the first silicon layer 461 and the silicon oxide layer 462 or between the silicon oxide layer 462 and the second silicon layer 463. That is, the sealing layer 46 may have a stacked structure of four or more layers.

The first silicon layer 461 is configured to contain silicon (Si), and is particularly constituted by silicon (Si) in this embodiment. Further, the silicon oxide layer 462 is configured to contain silicon oxide (SiO₂), and is particularly constituted by silicon oxide (SiO₂) in this embodiment. Further, the second silicon layer 463 is configured to contain silicon (Si), and is particularly constituted by silicon (Si) in this embodiment. As also described in the below-mentioned production method, the first silicon layer 461, the silicon oxide layer 462, and the second silicon layer 463 can be formed by any of various types of film forming methods such as a sputtering method and a CVD method.

In this manner, by configuring each of the layers 461, 462, and 463 to contain silicon (Si), as also described in the below-mentioned production method, the sealing layer 46 can be easily formed by a semiconductor process. Further, by sandwiching the silicon oxide layer 462 constituted by a different material (silicon oxide) from the material constituting the first silicon layer 461 and the second silicon layer 463 between the first silicon layer 461 and the second silicon layer 463 constituted by the same material (silicon), the thermal expansion coefficient can be averaged in the thickness direction, and the flexure in the out-of-plane direction at the time of thermal expansion of the sealing layer 46 can be suppressed. In particular, by suppressing the downward flexure of the sealing layer 46, the contact between the sealing layer 46 and the diaphragm 25 can be suppressed. When the sealing layer 46 comes into contact with the diaphragm 25, the flexural deformation of the diaphragm. 25 is inhibited, and therefore, the pressure detection accuracy is deteriorated. Due to this, as described above, by suppressing the flexure in the out-of-plane direction at the time of thermal expansion of the sealing layer 46 and suppressing the contact between the sealing layer 46 and the diaphragm 25, the pressure sensor 1 having excellent pressure detection accuracy is formed. Further, as described above, the substrate 2 is constituted by an SOT substrate, and therefore, the difference in the thermal expansion coefficient between the substrate 2 and the sealing layer 46 facing each other through the pressure reference chamber S can be decreased. As a result, the internal stress generated by thermal expansion can be suppressed small. Moreover, the change in the internal stress applied to the diaphragm 25 depending on the environmental temperature can be suppressed. Accordingly, for example, a decrease in the detection accuracy such that even if the same pressure is received, the pressure to be detected varies depending on the environmental temperature can be effectively suppressed.

The first silicon layer 461 and the second silicon layer 463 may each contain a material other than silicon (for example, a material inevitably mixed therein in the production). Similarly, the silicon oxide layer 462 may contain a material other than silicon oxide (for example, a material inevitably mixed therein in the production).

As shown in FIG. 1, in the first silicon layer 461, a plurality of through-holes 461a are formed. According to this, the first silicon layer 461 is easily deformed (expanded, contracted, etc.) in the plane direction thereof, and due to the deformation, for example, the internal stress of the pressure sensor 1 can be absorbed and relaxed. Therefore, the internal stress of the pressure sensor 1 is reduced, and the internal stress is less likely to be transmitted to the diaphragm 25. Accordingly, the pressure sensor 1 can exhibit excellent pressure detection accuracy.

Further, as described in the below-mentioned production method, each of the through-holes 461a is also used as a hole for release etching when removing a second sacrificial layer G2 which fills the pressure reference chamber S until the middle of the production. By also using the through-hole 461a for relaxing the stress as a hole for release etching, the configuration of the pressure sensor 1 is simplified, and also the production thereof is further simplified.

On the first silicon layer 461, the silicon oxide layer 462 is placed, and by this silicon oxide layer 462, the opening on the upper end side of each through-hole 461a is closed. According to this, the pressure reference chamber S is sealed.

The transverse cross-sectional shape of each through-hole 461a is an approximate circle. However, the transverse cross-sectional shape of each through-hole 461a is not particularly limited, and may be, for example, a polygon such as a triangle or a quadrangle, an ellipse, an irregular shape, or the like.

Further, as shown in FIG. 4, the through-hole 461a has a tapered shape in which the transverse cross-sectional area (diameter) gradually decreases from the pressure reference chamber S side to the silicon oxide layer 462 side. By forming the through-hole 461a into a tapered shape in this manner, the space in the through-hole 461a can be sufficiently ensured, so that the through-hole 461a can be more easily deformed, and also the opening on the upper side of the through-hole 461a can be sufficiently decreased. Due to this, the first silicon layer 461 can be more easily deformed in the in-plane direction, and also the opening on the upper end side of the through-hole 461a can be more reliably closed with the silicon oxide layer 462. In this embodiment, the through-hole 461a has a tapered shape in the entire region in the axial direction, however, the shape is not limited thereto, and at least apart thereof in the axial direction may suffice to have a tapered shape as described above.

As shown in FIG. 4, the diameter Rmax (width) of the opening on the lower end side of the through-hole 461a is not particularly limited, but is preferably 0.6 μm or more and 1.2 μm or less, more preferably 0.8 μm or more and 1.0 μm or less. According to this, a sufficiently large space in the through-hole 461a can be more reliably ensured, so that the first silicon layer 461 can be more easily deformed. Further, the through-hole 461a can be prevented from becoming excessively large, and for example, an excessive decrease in the mechanical strength of the first silicon layer 461 or an excessive increase in the thickness of the first silicon layer 461 for ensuring the mechanical strength of the first silicon layer 461 can be suppressed.

On the other hand, the diameter Rmin (width) of the opening on the upper end side of the through-hole 461a is not particularly limited, but is preferably 100 Å or more and 900 Å or less, more preferably 300 Å or more and 700 Å or less. According to this, the through-hole 461a which has a diameter with a sufficient size for performing etching for removing the second sacrificial layer G2 which fills the pressure reference chamber S and also can be more reliably closed with the silicon oxide layer 462 is formed.

Further, the changing ratio of the transverse cross-sectional area (diameter) of the through-hole 461a gradually decreases from the pressure reference chamber S side to the silicon oxide layer 462 side. That is, the inclination of the inner circumferential surface becomes steeper toward the upper side, and the upper end portion is in a state where the inner circumferential surface stands substantially vertically. Therefore, it can also be said that the through-hole 461a has a funnel-shaped inner space. According to such a configuration, the diameter of the through-hole 461a can be gradually decreased from the lower side to the upper side, and therefore, the diameter Rmin can be highly accurately controlled. Due to this, it becomes easy to adjust the diameter Rmin to the target value. That is, it is possible to prevent difficulty in removing the second sacrificial layer G2 by etching due to an excessive decrease in the diameter Rmin or difficulty in sealing the through-hole 461a with the silicon oxide layer 462 due to an excessive increase in the diameter Rmin. Accordingly, the second sacrificial layer G2 can be more reliably removed through the through-hole 461a, and also the through-hole 461a can be more reliably closed with the silicon oxide layer 462. The shape of the through-hole 461a is not particularly limited, and for example, the changing ratio of the transverse cross-sectional area (diameter) thereof may be constant toward the upper side.

As shown in FIGS. 1 and 4, the first silicon layer 461 has a frame shape (an annular shape) surrounding the opening on the lower end side of each through-hole 461a, and has a frame-shaped protrusion portion 461b which protrudes to the pressure reference chamber S side. According to this, even if the sealing layer 46 is flexed on the diaphragm 25 side and comes into contact with the diaphragm 25, the protrusion portion 461b preferentially comes into contact with the diaphragm 25. Due to this, as compared with a case where the protrusion portion 461b is not provided, the contact area between the sealing layer 46 and the diaphragm 25 can be made smaller, and the occurrence of “sticking” in which the sealing layer 46 sticks to the diaphragm 25 while being in contact therewith can be effectively suppressed. However, the protrusion portion 461b may be omitted.

Further, as shown in FIG. 4, the thickness T1 of the first silicon layer 461 is larger than the thickness T2 of the silicon oxide layer 462 and the thickness T3 of the second silicon layer 463. In the first silicon layer 461, a plurality of through-holes 461a are placed, and therefore, the mechanical strength thereof is likely to be decreased as compared with the other layers (the silicon oxide layer 462 and the second silicon layer 463). Due to this, by satisfying the following relationships: T1>T2 and T1>T3, a sufficient mechanical strength can be imparted to the first silicon layer 461.

Specifically, the thickness T1 of the first silicon layer 461 is not particularly limited, but is preferably, for example, 1 μm or more and 10 μm or less, more preferably 2 μm or more and 7 μm or less. According to this, while imparting a sufficient mechanical strength to the first silicon layer 461, an excessive increase in the thickness of the first silicon layer 461 can be prevented. Further, the through-hole 461a having the diameters Rmax and Rmin as described above can be more easily formed.

On the first silicon layer 461 as described above, the silicon oxide layer 462 is stacked. The silicon oxide layer 462 is a layer mainly for sealing the plurality of through-holes 461a provided in the first silicon layer 461. The thickness T2 of such a silicon oxide layer 462 is not particularly limited, but is preferably, for example, 1 μm or more and 5 μm or less, more preferably 1.5 μm or more and 2.5 μm or less. According to this, while preventing an excessive increase in the thickness of the silicon oxide layer 462, the through-holes 461a can be more reliably sealed with the silicon oxide layer 462.

On the silicon oxide layer 462 as described above, the second silicon layer 463 is stacked. The second silicon layer 463 is a layer mainly for suppressing the flexure in the out-of-plane direction at the time of thermal expansion of the sealing layer 46 by sandwiching the silicon oxide layer 462 constituted by a different material between the second silicon layer 463 and the first silicon layer 461 constituted by the same material. According to this, particularly, the downward flexure of the sealing layer 46 can be suppressed, and the contact between the sealing layer 46 and the diaphragm 25 can be suppressed.

Here, when the silicon oxide layer 462 is exposed to the outside, the silicon oxide layer 462 adsorbs water, and there is a fear that the internal stress of the sealing layer 46 may change depending on the environmental humidity. When the internal stress of the sealing layer 46 changes depending on the environmental humidity in this manner, also the internal stress of the diaphragm 25 changes accompanying this. Due to this, even if the same pressure is received, the measured value varies depending on the environmental humidity, and the pressure detection accuracy of the pressure sensor 1 may be deteriorated.

Therefore, in this embodiment, by covering the silicon oxide layer 462 with the second silicon layer 463, the silicon oxide layer 462 is airtightly sealed from the outside of the pressure sensor 1. That is, the surface, which can be exposed to the outside, of the silicon oxide layer 462 is covered with the second silicon layer 463 and the exposure of the silicon oxide layer 462 to the outside is prevented. According to this, the silicon oxide layer 462 can be protected from water, and therefore, the change in the internal stress of the sealing layer 46 depending on the environmental humidity can be suppressed.

In this embodiment, the side surfaces of the silicon oxide layer 462 are covered with the second silicon layer 463, however, the configuration is not limited thereto, and the side surfaces of the silicon oxide layer 462 may be covered with the first silicon layer 461, or may be covered with both of the first silicon layer 461 and the second silicon layer 463. Further, for example, in a case where the pressure sensor is used in an environment where the pressure sensor is less likely to be affected by the humidity, for example, in an environment where the humidity is constant or the like, the silicon oxide layer 462 may not be sealed with the second silicon layer 463, and the silicon oxide layer 462 may be exposed to the outside.

The thickness T3 of such a second silicon layer 463 is not particularly limited, but is preferably set to, for example, 0.1 μm or more and 10 μm or less, more preferably set to 0.3 μm or more and 1.0 μm or less. According to this, it is possible to obtain a balance with the thickness of the first silicon layer 461, and the flexure in the out-of-plane direction at the time of thermal expansion of the sealing layer can be more effectively suppressed. Further, the occurrence of a pinhole in the second silicon layer 463 can be suppressed, and the silicon oxide layer 462 can be more reliably sealed between the second silicon layer 463 and the first silicon layer 461. Due to this, the silicon oxide layer 462 can be more effectively protected from water. Further, an excessive increase in the thickness of the second silicon layer 463 can be prevented.

Hereinabove, the pressure sensor 1 has been described. As described above, such a pressure sensor 1 includes the substrate 2 having the diaphragm 25 which is flexurally deformed by receiving a pressure, the side wall section 4A which is placed on the upper surface (one surface) side of the substrate 2 and is disposed so as to surround the diaphragm 25 in a plan view, and the sealing layer 46 which is placed so as to face the diaphragm 25 through the pressure reference chamber S (space) formed inside the side wall section 4A and seals the pressure reference chamber S. Further, the sealing layer 46 includes the first silicon layer 461 which has the through-holes 461a facing the pressure reference chamber S, the silicon oxide layer 462 which is located on the opposite side to the pressure reference chamber S with respect to the first silicon layer 461 (on the upper side) and seals the through-holes 461a, and the second silicon layer 463 which is located on the opposite side to the pressure reference chamber S with respect to the silicon oxide layer 462 (on the upper side). By placing the through-holes 461a in the first silicon layer 461 in this manner, the sealing layer 46 is easily deformed in the plane direction thereof. Due to this, the internal stress of the pressure sensor 1 is relaxed by the sealing layer 46, and the internal stress is less likely to be transmitted to the diaphragm 25. Accordingly, the pressure sensor 1 which can suppress the change in the internal stress applied to the diaphragm 25 depending on the environmental temperature, and can exhibit excellent pressure detection accuracy is formed.

Further, as described above, in the pressure sensor 1, the through-hole 461a has a portion in which the transverse cross-sectional area gradually decreases from the pressure reference chamber S (space) side to the silicon oxide layer 462 side. According to this, the space in the through-hole 461a can be sufficiently ensured, so that the through-hole 461a can be more easily deformed, and also the opening on the upper side of the through-hole 461a can be sufficiently decreased. Due to this, the sealing layer 46 is more easily deformed in the in-plane direction, and also the opening on the upper end side of the through-hole 461a can be more reliably closed with the silicon oxide layer 462. In particular, in this embodiment, the through-hole 461a has a tapered shape in the entire region in the axial direction of the through-hole 461a, and therefore, the above-mentioned effect becomes more prominent.

Further, as described above, in the pressure sensor 1, the through-hole 461a has a portion in which the changing ratio of the transverse cross-sectional area gradually decreases from the pressure reference chamber S (space) side to the silicon oxide layer 462 side. According to this, on the upper end side of the through-hole 461a, the change in the transverse cross-sectional area becomes gradual, and therefore, it becomes easy to control the size of the diameter Rmin of the opening on the upper end side. Due to this, it becomes easy to adjust the diameter Rmin to the target value.

Further, as described above, in the pressure sensor 1, the first silicon layer 461 is placed so as to surround the opening (the opening on the lower end side) of the through-hole 461a, and has the protrusion portion 461b which protrudes to the pressure reference chamber S (space) side. According to this, even if the sealing layer 46 is flexed on the diaphragm 25 side and comes into contact with the diaphragm 25, the protrusion portion 461b preferentially comes into contact with the diaphragm 25. Due to this, as compared with a case where the protrusion portion 461b is not provided, the contact area between the sealing layer 46 and the diaphragm 25 can be made smaller, and the occurrence of “sticking” in which the sealing layer 46 sticks to the diaphragm 25 while being in contact therewith can be effectively suppressed.

Further, as described above, in the pressure sensor 1, the silicon oxide layer 462 is sealed from the outside by being covered with the second silicon layer 463. According to this, the silicon oxide layer 462 can be protected from water, and therefore, the change in the internal stress of the sealing layer 46 depending on the environmental humidity can be suppressed.

Further, as described above, in the pressure sensor 1, the first silicon layer 461 is thicker than the second silicon layer 463 and the silicon oxide layer 462. In the first silicon layer 461, a plurality of through-holes 461a are placed, and therefore, the mechanical strength thereof is likely to be decreased as compared with the other layers (the silicon oxide layer 462 and the second silicon layer 463). Due to this, as described above, by satisfying the following relationships: T1>T2 and T1>T3, a sufficient mechanical strength can be imparted to the first silicon layer 461.

Next, a production method for the pressure sensor 1 will be described. As shown in FIG. 5, the production method for the pressure sensor 1 includes a preparation step of preparing the substrate 2 which has a diaphragm forming region 250, a sensor section placing step of placing the sensor section 5, a sacrificial layer placing step of placing the sacrificial layer G on the upper surface (one surface) side of the substrate 2 so as to overlap with the diaphragm forming region 250 in a plan view, a first silicon layer placing step of placing the first silicon layer 461 which has the through-holes 461a facing the sacrificial layer G and contains silicon on the upper surface (the surface on the opposite side to the substrate 2) side of the sacrificial layer G, a sacrificial layer removing step of removing the sacrificial layer G through the through-holes 461a, a silicon oxide layer placing step of placing the silicon oxide layer 462 containing silicon oxide on the upper surface (the surface on the opposite side to the substrate 2) side of the first silicon layer 461 so as to seal the through-holes 461a, a second silicon layer placing step of placing the second silicon layer 463 containing silicon on the upper surface (the surface on the opposite side to the substrate 2) side of the silicon oxide layer 462, and a diaphragm forming step of forming the diaphragm 25 which is flexurally deformed by receiving a pressure in the diaphragm forming region 250 of the substrate 2.

### Preparation Step

First, as shown in FIG. 6, the substrate 2 composed of an SOI substrate in which the first layer 21, the second layer 22, and the third layer 23 are stacked is prepared. In this stage, the diaphragm 25 is not formed in the diaphragm forming region 250 of the substrate 2. Subsequently, for example, by thermally oxidizing the surface of the third layer 23, the first insulating film 31 composed of a silicon oxide film is formed on the upper surface of the substrate 2.

### Sensor Section Placing Step

Subsequently, as shown in FIG. 7, the sensor section 5 is formed on the upper surface of the substrate 2 by injecting an impurity such as phosphorus or boron thereinto. Subsequently, the second insulating film 32 and the conductive film 33 are formed on the upper surface of the first insulating film 31 by a sputtering method, a CVD method, or the like.

### Sacrificial Layer Placing Step

Subsequently, as shown in FIG. 8, on the substrate 2, the interlayer insulating film 41, the wiring layer 42, the interlayer insulating film 43, the wiring layer 44, the surface protective film 45, and the terminal 47 are sequentially formed in predetermined patterns using a sputtering method, a CVD method, or the like. By doing this, the frame-shaped side wall section 4A surrounding the diaphragm forming region 250 in a plan view of the substrate 2, and the sacrificial layer G surrounded by the guard rings 421 and 441 are obtained. Here, the sacrificial layer G includes a first sacrificial layer G1 constituted by the interlayer insulating films 41 and 43, and a second sacrificial layer G2 placed on the upper surface of the first sacrificial layer G1 and formed integrally with the guard ring 441. Further, in the second sacrificial layer G2, a through-hole G21 penetrating therethrough in the thickness direction is formed. In this embodiment, the interlayer insulating films 41 and 43 are constituted by silicon oxide, and the wiring layers 42 and 44 are constituted by aluminum.

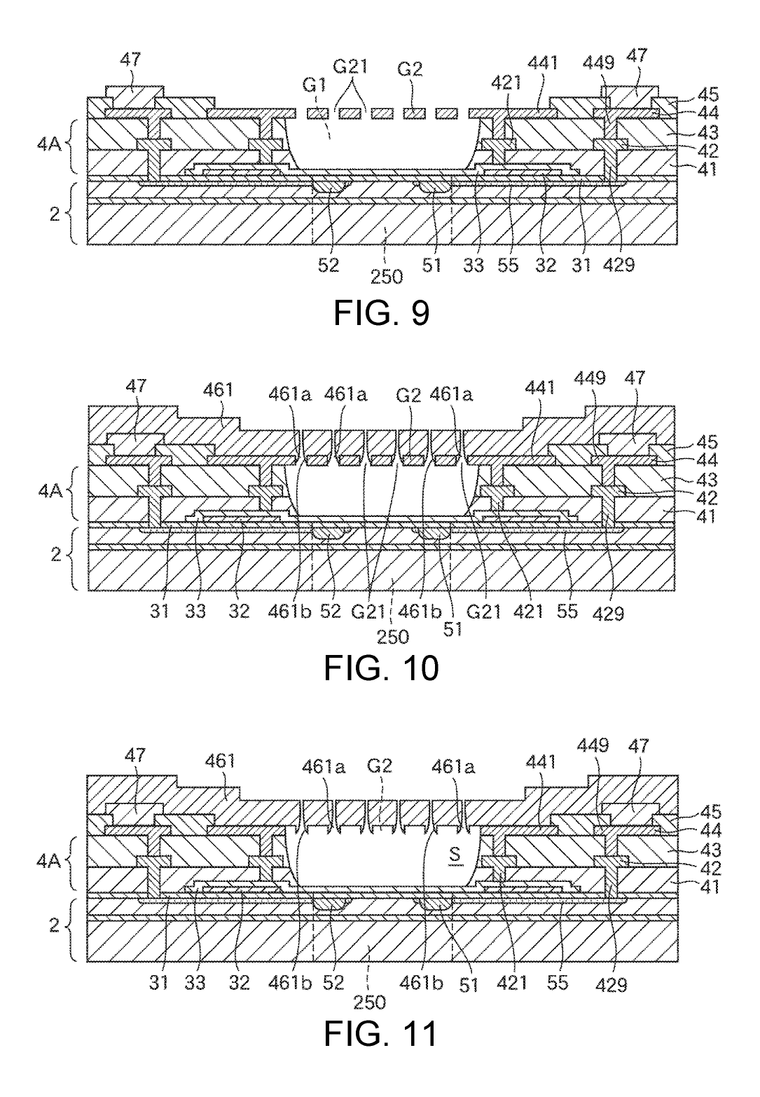

Subsequently, the substrate 2 is exposed to an etching solution such as buffered hydrofluoric acid. By doing this, as shown in FIG. 9, the first sacrificial layer G1 (the interlayer insulating films 41 and 43 located inside the guard rings 421 and 441) is removed by etching through the through-hole G21. At this time, the guard rings 421 and 441 and the conductive film 33 each function as an etching stopper. In this embodiment, a part of the first sacrificial layer G1 is not removed and remains, however, the entire first sacrificial layer G1 may be removed in this step.

### First Silicon Layer Placing Step

Subsequently, as shown in FIG. 10, on the upper surface of the second sacrificial layer G2 and the surface protective film 45, the first silicon layer 461 having a through-hole 461a is formed. The film forming method for the first silicon layer 461 is not particularly limited, and for example, various types of film forming methods (vapor deposition methods) such as a sputtering method and a CVD method can be used.

Here, this step will be more specifically described. When the first silicon layer 461 is grown on the second sacrificial layer G2, the through-hole G21 is rapidly filled up at the beginning, however, as the first silicon layer 461 becomes thick, the filling up rate is decreased, and from around the time when the thickness of the first silicon layer 461 exceeds a certain value, the through-hole G21 is almost no longer filled up. This is considered to be because a space is formed beforehand on the lower side of the through-hole G21 by removing the first sacrificial layer G1 in the previous step, and an Si atom having passed through the through-hole G21 is released to this space, so that the closure of the through-hole G21 is suppressed. In this manner, by forming the first silicon layer 461 in a state where a space has been formed on the lower side of the second sacrificial layer G2, the through-hole 461a can be easily and more reliably formed. Further, by allowing a part of the first silicon layer 461 to penetrate into the through-hole G21, the frame-shaped protrusion portion 461b is formed. In view of this, it can also be said that the second sacrificial layer G2 has a function as a foundation layer for forming the through-hole 461a and the protrusion portion 461b in the first silicon layer 461.

### Sacrificial Layer Removing Step

Subsequently, the substrate 2 is, for example, exposed to an etching solution such as a mixed acid of phosphoric acid, acetic acid, and nitric acid, whereby the second sacrificial layer G2 is removed through the through-hole 461a. By doing this, as shown in FIG. 11, the pressure reference chamber S is formed. The second sacrificial layer G2 is located in the vicinity of the through-hole 461a, and therefore is removed by etching preferentially to the guard rings 421 and 441 constituted by the same material. Due to this, in this step, the second sacrificial layer G2 can be removed while leaving the guard rings 421 and 441.

### Silicon Oxide Layer Placing Step

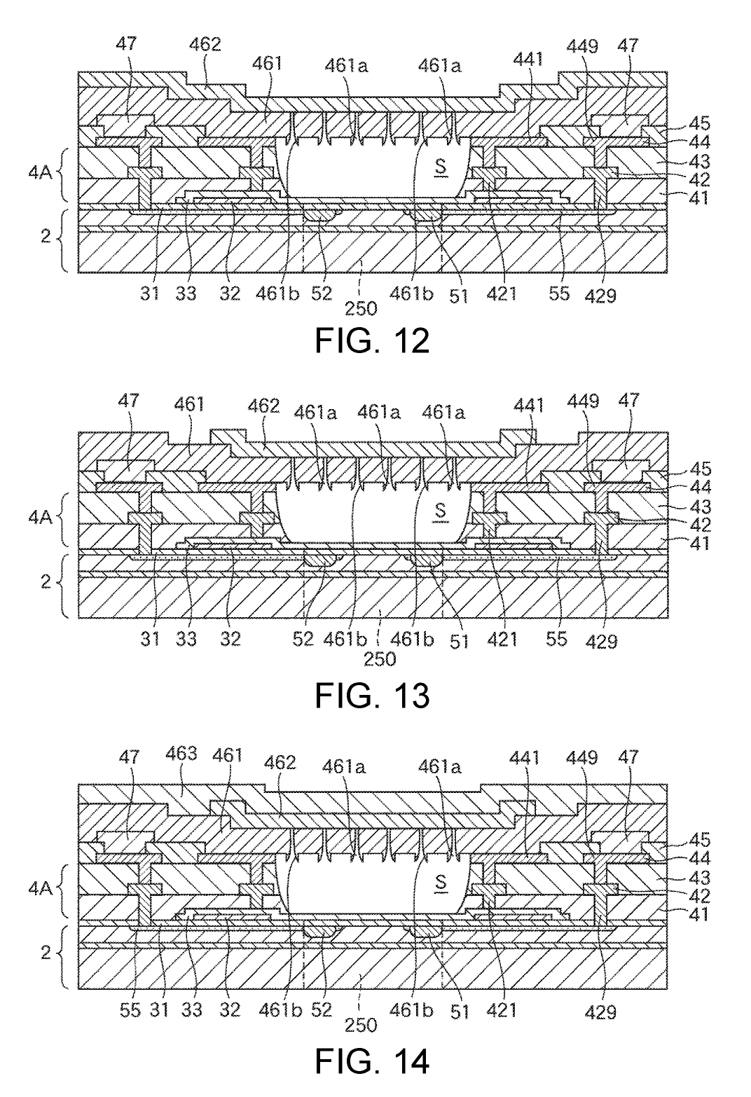

Subsequently, as shown in FIG. 12, the silicon oxide layer 462 is formed on the upper surface of the first silicon layer 461 in a state where the pressure reference chamber S is brought into a vacuum state through the through-hole 461a so as to seal the through-hole 461a. The film forming method for the silicon oxide layer 462 is not particularly limited, and for example, various types of film forming methods (vapor deposition methods) such as a sputtering method and a CVD method can be used.

Subsequently, as shown in FIG. 13, the silicon oxide layer 462 is patterned using a photolithographic technique and an etching technique so as to locate the outer edge of the silicon oxide layer 462 inside the outer edge of the first silicon layer 461. As the patterning method for the silicon oxide layer 462, it is preferred to utilize wet etching using an etching solution such as buffered hydrofluoric acid. According to this, a large etching selection ratio between the silicon oxide layer 462 and the first silicon layer 461 can be ensured, and substantially only the silicon oxide layer 462 can be patterned.

### Second Silicon Layer Placing Step

Subsequently, as shown in FIG. 14, on the upper surfaces of the first silicon layer 461 and the silicon oxide layer 462, the second silicon layer 463 is formed. By doing this, the silicon oxide layer 462 is sealed with the first silicon layer 461 and the second silicon layer 463. The film forming method for the second silicon layer 463 is not particularly limited, and for example, various types of film forming methods (vapor deposition methods) such as a sputtering method and a CVD method can be used.

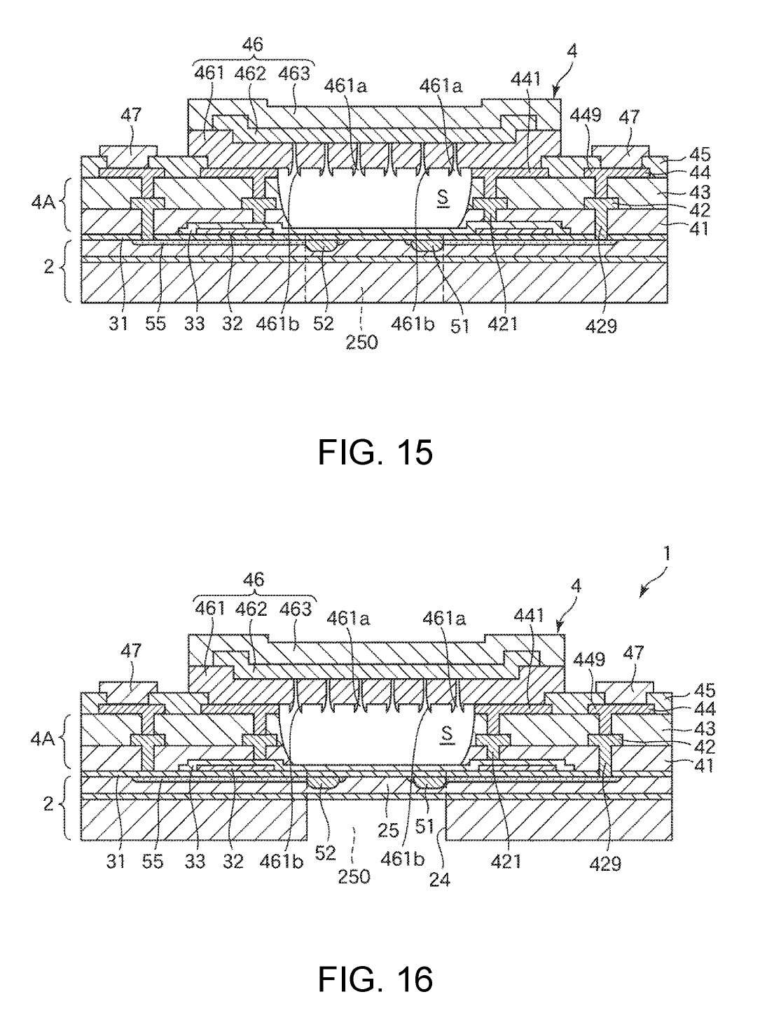

Subsequently, as shown in FIG. 15, the first silicon layer 461 and the second silicon layer 463 are simultaneously patterned using a photolithographic technique and an etching technique. By doing this, the sealing layer 46 is obtained. By forming the first silicon layer 461 and the second silicon layer 463 from the same material, these layers can be simultaneously patterned. Therefore, the production step of the pressure sensor 1 can be reduced, and thus, it becomes easier to produce the pressure sensor 1.

### Diaphragm Forming Step

Subsequently, as shown in FIG. 16, by etching the first layer 21 using, for example, a dry etching (particularly, silicon deep etching) method, the recessed section 24 which opens to the lower surface is formed in the diaphragm forming region 250, whereby the diaphragm 25 is obtained. As described above, the pressure sensor 1 is obtained. The order of the diaphragm forming step is not particularly limited, and for example, the diaphragm forming step may be performed prior to the sensor section placing step, or may be performed between the sensor section placing step and the second silicon layer placing step.

Hereinabove, the production method for the pressure sensor 1 has been described. As described above, the production method for the pressure sensor 1 includes a step of preparing the substrate 2 having the diaphragm forming region 250, a step of placing the sacrificial layer G on the upper surface (one surface) side of the substrate 2 so as to overlap with the diaphragm forming region 250 in a plan view, a step of placing the first silicon layer 461 which has the through-holes 461a facing the sacrificial layer G on the opposite side to the substrate 2 with respect to the sacrificial layer G (on the upper side), a step of removing at least a part of the sacrificial layer G through the through-holes 461a, a step of placing the silicon oxide layer 462 on the opposite side to the substrate 2 with respect to the first silicon layer 461 (on the upper side) so as to seal the through-holes 461a, a step of placing the second silicon layer 463 on the opposite side to the substrate 2 with respect to the silicon oxide layer 462 (on the upper side), and a step of forming the diaphragm 25 which is flexurally deformed by receiving a pressure in the diaphragm forming region 250 of the substrate 2. According to this, the sealing layer 46 which is easily deformed in the in-plane direction is obtained. Therefore, the internal stress of the pressure sensor 1 is relaxed by the sealing layer 46, and the internal stress is less likely to be transmitted to the diaphragm 25. Accordingly, the change in the internal stress applied to the diaphragm 25 depending on the environmental temperature can be suppressed, and the pressure sensor 1 capable of exhibiting excellent pressure detection accuracy is obtained.

### Second Embodiment

Next, a pressure sensor according to a second embodiment of the invention will be described.

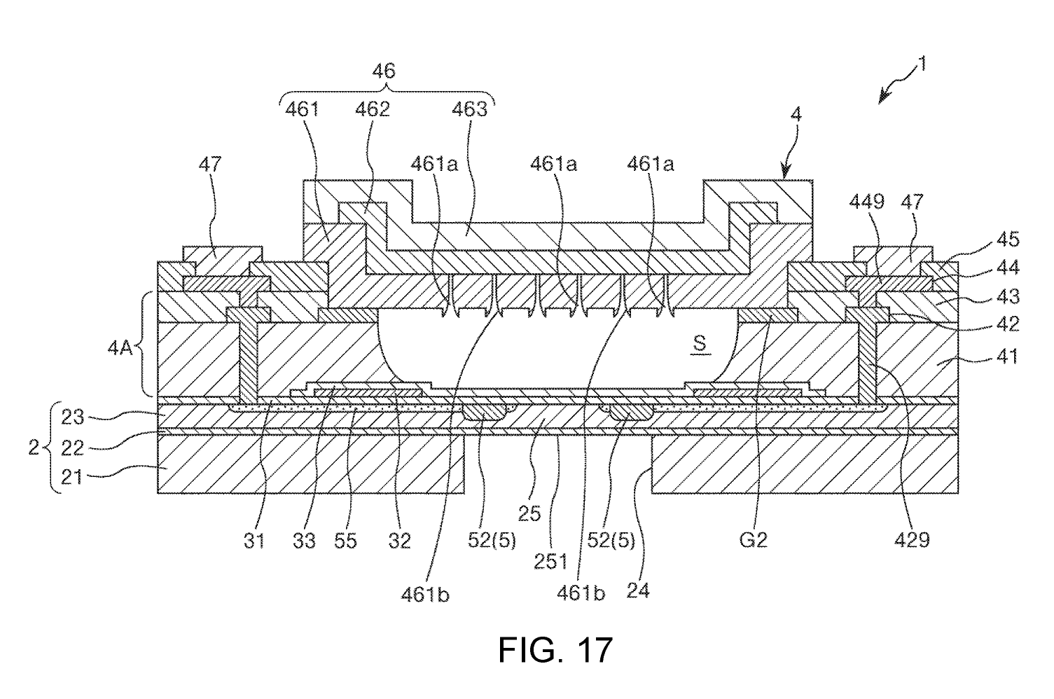

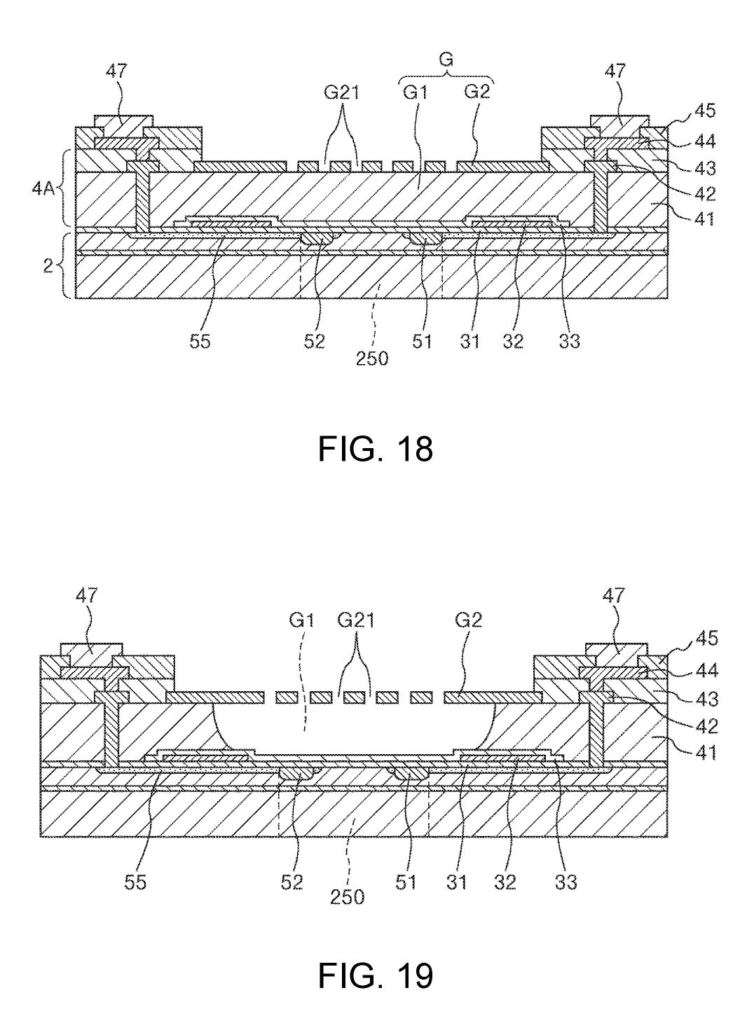

FIG. 17 is a cross-sectional view showing the pressure sensor according to the second embodiment of the invention. FIGS. 18 to 21 are cross-sectional views for illustrating a production method for the pressure sensor shown in FIG. 17.

A pressure sensor 1 according to this embodiment is substantially the same as the pressure sensor 1 according to the first embodiment described above except that the configuration of the surrounding structure 4 is different.

Hereinafter, with respect to the pressure sensor 1 according to the second embodiment, different points from the above-mentioned first embodiment will be mainly described, and the description of the same matter will be omitted. The same components as those of the above-mentioned embodiment are denoted by the same reference numerals.

As shown in FIG. 17, in the pressure sensor 1 according to this embodiment, the surrounding structure 4 has a configuration in which the guard rings 421 and 441 are omitted from the configuration of the above-mentioned first embodiment. That is, the interlayer insulating film 41 and the interlayer insulating film 43 face the pressure reference chamber S (constitute the side walls of the pressure reference chamber S). In the pressure sensor 1 according to the first embodiment, the guard rings 421 and 441 are constituted by a relatively hard metal material such as aluminum, and further placed so as to connect the sealing layer 46 to the diaphragm 25 (see FIG. 1). Therefore, the internal stress of the sealing layer 46 is likely to be transmitted to the diaphragm 25 through the guard rings 421 and 441. On the other hand, in this embodiment, the guard rings 421 and 441 are omitted, and therefore, the internal stress of the sealing layer 46 is less likely to be transmitted to the diaphragm 25 as compared with the above-mentioned first embodiment. Accordingly, the change in the internal stress applied to the diaphragm 25 attributed to the environmental temperature can be suppressed small, and thus, the pressure sensor 1 capable of exhibiting excellent pressure detection accuracy is obtained.

In this embodiment, apart of the second sacrificial layer G2 remains, however, the entire second sacrificial layer G2 may be removed. Further, depending on the thickness of the interlayer insulating layer 43, the interlayer insulating layer 43 may be configured to have a stacked structure of two or more layers, and in this case, a wiring layer may be placed between the layers.

Next, a production method for the pressure sensor according to this embodiment will be described. The production method for the pressure sensor 1 according to this embodiment includes a preparation step, a sensor section placing step, a sacrificial layer placing step, a first silicon layer placing step, a sacrificial layer removing step, a silicon oxide layer placing step, a second silicon layer placing step, and a diaphragm forming step in the same manner as in the above-mentioned first embodiment. Among these steps, the steps from the sacrificial layer placing step to the sacrificial layer removing step are different from those of the above-mentioned first embodiment, and therefore, only the steps from the sacrificial layer placing step to the sacrificial layer removing step will be described below.

### Sacrificial Layer Placing Step

As shown in FIG. 18, on the substrate 2, the interlayer insulating film 41, the wiring layer 42, the interlayer insulating film 43, the wiring layer 44, the surface protective film 45, and the terminal 47 are sequentially formed in predetermined patterns using a sputtering method, a CVD method, or the like. By doing this, the frame-shaped side wall section 4A surrounding the diaphragm forming region 250 in a plan view of the substrate 2, and the sacrificial layer G placed in the side wall section 4A are obtained. Here, the sacrificial layer G includes a first sacrificial layer G1 constituted by the interlayer insulating film 41, and a second sacrificial layer G2 placed on the first sacrificial layer G1 and formed from the wiring layer 42. Further, in the second sacrificial layer G2, the through-hole G21 facing the first sacrificial layer G1 is formed.

Subsequently, the substrate 2 is exposed to an etching solution such as buffered hydrofluoric acid. By doing this, as shown in FIG. 19, the first sacrificial layer G1 is removed through the through-hole G21 of the second sacrificial layer G2.

### First Silicon Layer Placing Step

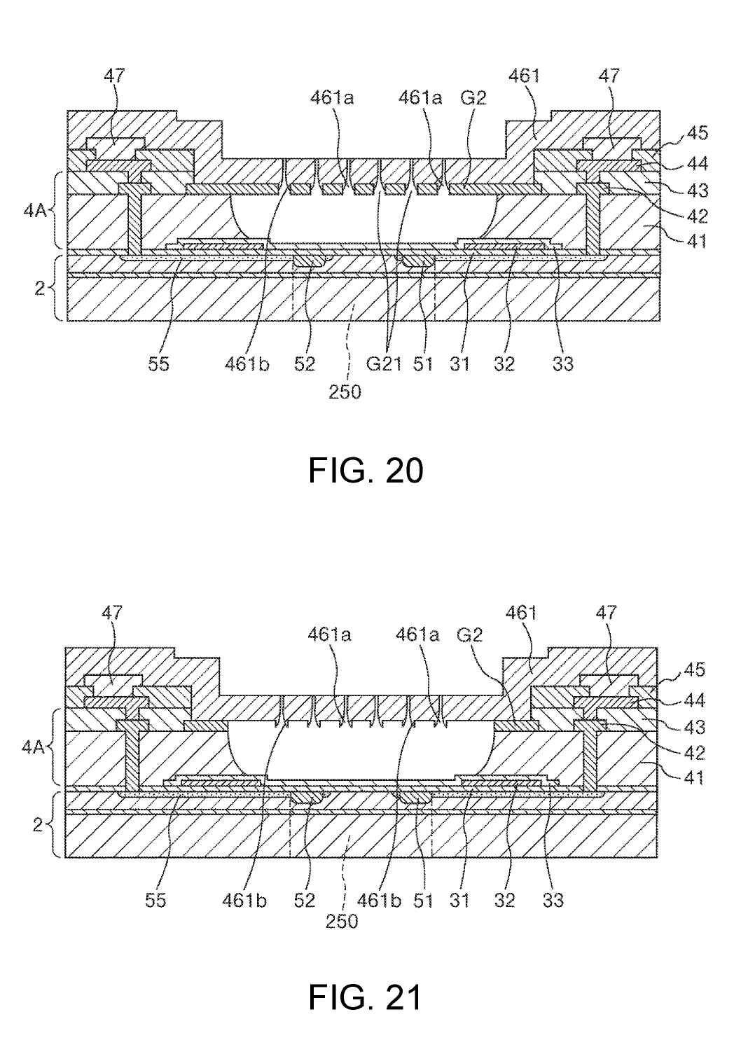

Subsequently, as shown in FIG. 20, on the upper surface of the second sacrificial layer G2 and the surface protective film 45, the first silicon layer 461 having a through-hole 461a is formed. The film forming method for the first silicon layer 461 is not particularly limited, and for example, various types of film forming methods (vapor deposition methods) such as a sputtering method and a CVD method can be used.

### Sacrificial Layer Removing Step

Subsequently, the substrate 2 is, for example, exposed to an etching solution such as a mixed acid of phosphoric acid, acetic acid, and nitric acid so as to remove the second sacrificial layer G2 through the through-hole 461a. By doing this, as shown in FIG. 21, the pressure reference chamber S is formed. In this manner, the side wall section 4A which does not have the guard rings 421 and 441 is obtained. In FIG. 21, a part of the second sacrificial layer G2 is not removed and remains, however, the entire second sacrificial layer G2 may be removed in this step.

According also to the second embodiment as described above, the same effect as that of the above-mentioned first embodiment can be exhibited.

### Third Embodiment

Next, a pressure sensor module according to a third embodiment of the invention will be described.

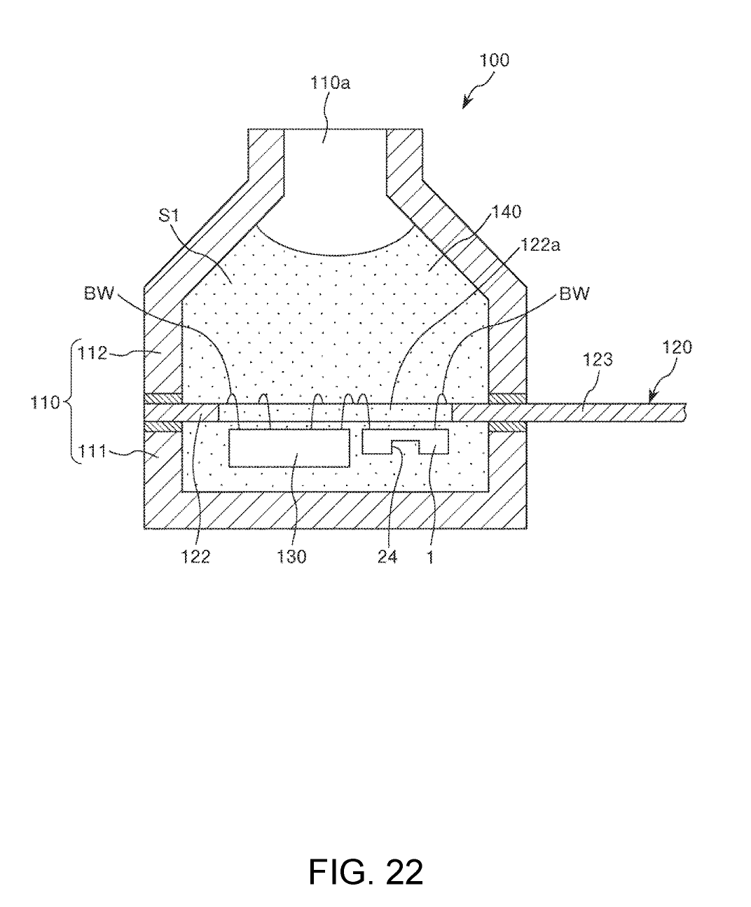

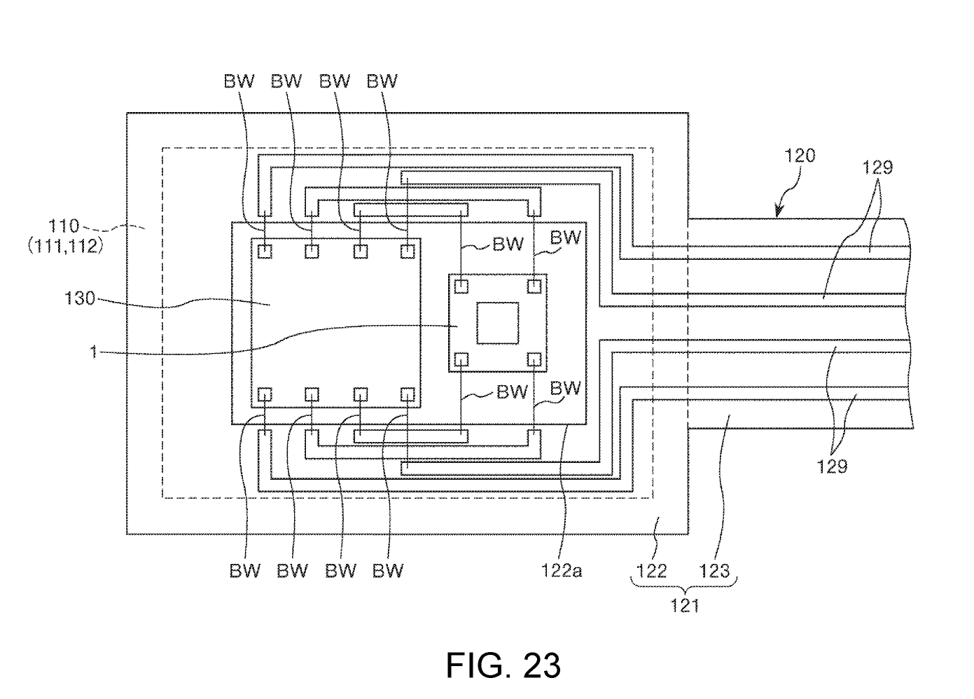

FIG. 22 is a cross-sectional view showing the pressure sensor module according to the third embodiment of the invention. FIG. 23 is a plan view of a support substrate included in the pressure sensor module shown in FIG. 22.

Hereinafter, with respect to the pressure sensor module according to the third embodiment, different points from the above-mentioned embodiment will be mainly described, and the description of the same matter will be omitted.

As shown in FIG. 22, a pressure sensor module 100 includes a package 110 which has an internal space S1, a support substrate 120 which is placed so as to be drawn out from the inside of the internal space S1 to the outside of the package 110, a circuit element 130 and a pressure sensor 1, each of which is supported by the support substrate 120 in the internal space S1, and a filling section 140 which is formed by filling a filler as described later in the internal space S1. According to such a pressure sensor module 100, the pressure sensor 1 can be protected by the package 110 and the filling section 140. As the pressure sensor 1, for example, the pressure sensor according to the embodiment described above can be used.

The package 110 includes a base 111 and a housing 112, and the base 111 and the housing 112 are bonded to each other through an adhesive layer so as to sandwich the support substrate 120 therebetween. The package 110 formed in this manner includes an opening 110a formed in the upper end portion thereof and the internal space S1 communicating with the opening 110a.

The constituent material of the base 111 and the housing 112 is not particularly limited, and examples thereof include insulating materials such as various types of ceramics including oxide ceramics such as alumina, silica, titania, and zirconia, and nitride ceramics such as silicon nitride, aluminum nitride, and titanium nitride, and various types of resin materials including polyethylene, polyamide, polyimide, polycarbonate, acrylic resins, ABS resins, and epoxy resins, and among these, it is possible to use one type or two or more types in combination. Above all, it is particularly preferred to use various types of ceramics.

Hereinabove, the package 110 has been described, however, the configuration of the package 110 is not particularly limited as long as the function can be exhibited.

The support substrate 120 is sandwiched between the base 111 and the housing 112 and placed so as to be drawn out from the inside of the internal space S1 to the outside of the package 110. Further, the support substrate 120 supports the circuit element 130 and the pressure sensor 1, and also electrically connects the circuit element 130 and the pressure sensor 1. Such a support substrate 120 includes a base material 121 having flexibility and a plurality of wirings 129 placed on the base material 121 as shown in FIG. 23.

The base material 121 includes a frame-shaped base section 122 having an opening 122a and a strip-shaped belt body 123 extending from the base section 122. The belt body 123 is sandwiched between the base 111 and the housing 112 in the outer edge portion of the base section 122 and extends to the outside of the package 110. As such a base material 121, for example, a generally used flexible printed circuit board can be used. In this embodiment, the base material 121 has flexibility, however, the entire or apart of the base material 121 may be a hard material.

The circuit element 130 and the pressure sensor 1 are located inside the opening 122a and are placed side by side in a plan view of the base material 121. Further, each of the circuit element 130 and the pressure sensor 1 is hung on the base material 121 through a bonding wire BW and is supported by the support substrate 120 in a floating state from the support substrate 120. Further, the circuit element 130 and the pressure sensor 1 are electrically connected through the bonding wires BW and the wirings 129. In this manner, by supporting the circuit element 130 and the pressure sensor 1 in a floating state with respect to the support substrate 120, a stress is less likely to be transmitted to the circuit element 130 and the pressure sensor 1 from the support substrate 120, and therefore, the pressure detection accuracy of the pressure sensor 1 is improved.

The circuit element 130 includes a drive circuit for supplying a voltage to the bridge circuit 50, a temperature compensation circuit for performing temperature compensation of an output from the bridge circuit 50, a pressure detection circuit which determines a pressure received from an output from the temperature compensation circuit, an output circuit which converts an output from the pressure detection circuit into a predetermined output form (CMOS, LV-PECL, LVDS, or the like) and outputs the converted output, and the like.

The filling section 140 is placed in the internal space S1 so as to cover the circuit element 130 and the pressure sensor 1. By such a filling section 140, the circuit element 130 and the pressure sensor 1 are protected (protected from dust and water), and also an external stress (for example, a drop impact) having acted on the pressure sensor 1 is less likely to be transmitted to the circuit element 130 and the pressure sensor 1.

Further, the filling section 140 can be constituted by a liquid or gel-like filler, and is particularly preferably constituted by a gel-like filler from the standpoint that an excessive displacement of the circuit element 130 and the pressure sensor 1 can be suppressed. According to such a filling section 140, the circuit element 130 and the pressure sensor 1 can be effectively protected from water, and also a pressure can be efficiently transmitted to the pressure sensor 1. The filler constituting such a filling section 140 is not particularly limited, and for example, a silicone oil, a fluorine-based oil, a silicone gel, or the like can be used.

Hereinabove, the pressure sensor module 100 has been described. Such a pressure sensor module 100 includes the pressure sensor 1 and the package 110 which houses the pressure sensor 1. Therefore, the pressure sensor 1 can be protected by the package 110. Further, the effect of the pressure sensor 1 described above can be received, and high reliability can be exhibited.

The configuration of the pressure sensor module 100 is not limited to the above-mentioned configuration, and for example, the filling section 140 may be omitted. Further, in this embodiment, the pressure sensor 1 and the circuit element 130 are supported in a state of being hung on the support substrate 120 by the bonding wires BW, however, for example, the pressure sensor 1 and the circuit element 130 may be placed directly on the support substrate 120. Further, in this embodiment, the pressure sensor 1 and the circuit element 130 are placed side by side in the lateral direction, however, for example, the pressure sensor 1 and the circuit element 130 may be placed side by side in the height direction.

### Fourth Embodiment

Next, an electronic apparatus according to a fourth embodiment of the invention will be described.

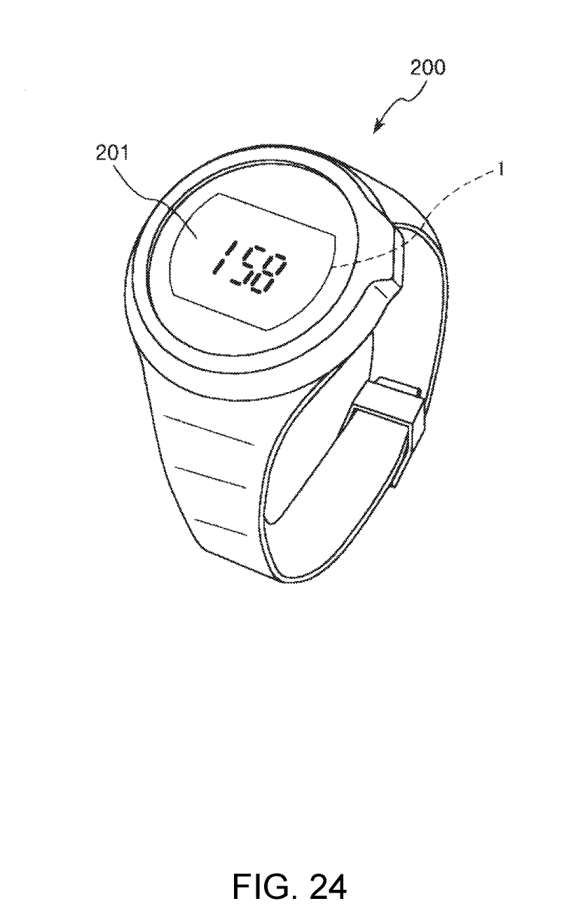

FIG. 24 is a perspective view showing an altimeter as the electronic apparatus according to the fourth embodiment of the invention.

As shown in FIG. 24, an altimeter 200 as the electronic apparatus can be worn on the wrist like a wristwatch. In the altimeter 200, the pressure sensor 1 is mounted, and the altitude of the current location above sea level, the atmospheric pressure at the current location, or the like can be displayed on a display section 201. In this display section 201, various information such as a current time, the heart rate of a user, and weather can be displayed.

Such an altimeter 200 which is one example of the electronic apparatus includes the pressure sensor 1. Therefore, the altimeter 200 can receive the effect of the pressure sensor 1 described above and can exhibit high reliability.

### Fifth Embodiment

Next, an electronic apparatus according to a fifth embodiment of the invention will be described.

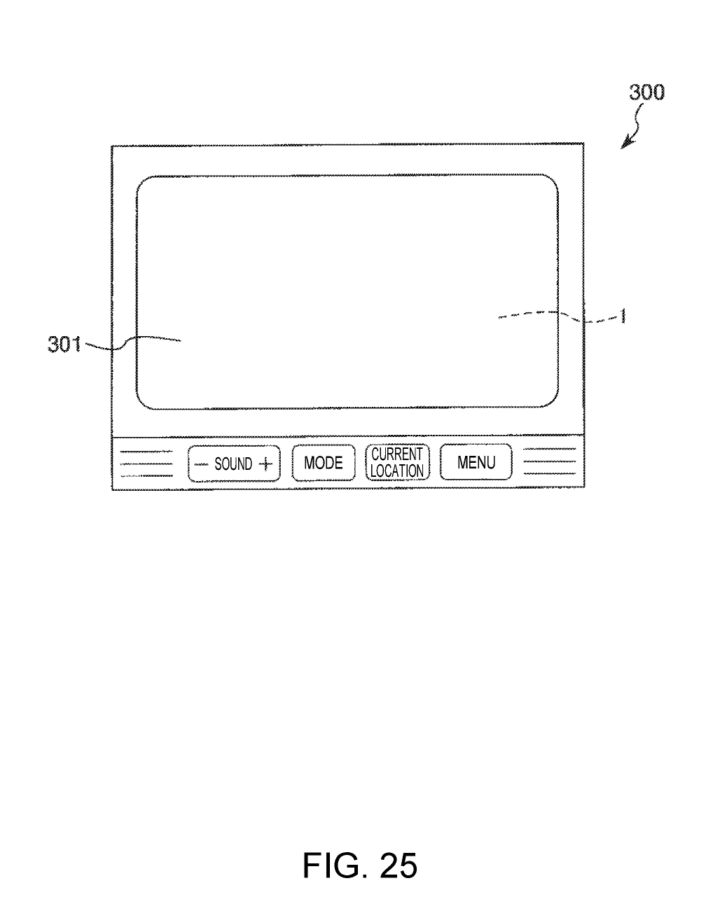

FIG. 25 is a front view showing a navigation system as the electronic apparatus according to the fifth embodiment of the invention.

As shown in FIG. 25, a navigation system 300 as the electronic apparatus includes map information (not shown), a location information acquisition unit based on a GPS (Global Positioning System), a self-contained navigation unit based on a gyroscope sensor, an accelerometer, and a vehicle speed data, the pressure sensor 1, and a display section 301 which displays given location information or route information.

According to this navigation system 300, in addition to the acquired location information, altitude information can be acquired. For example, in a case where a vehicle travels on an elevated road which is at substantially the same location as a general road in terms of location information, if altitude information is not provided, a navigation system cannot determine whether the vehicle is traveling on the general road or on the elevated road, and provides the user with information of the general road as priority information. Therefore, by mounting the pressure sensor 1 on the navigation system 300 and acquiring altitude information by the pressure sensor 1, the change in altitude due to entry into the elevated road from the general road can be detected, and the user can be provided with navigation information for the state of traveling on the elevated road.

Such a navigation system 300 as one example of the electronic apparatus includes the pressure sensor 1. Therefore, the navigation system 300 can receive the effect of the pressure sensor 1 described above and can exhibit high reliability.

The electronic apparatus according to the invention is not limited to the above-mentioned altimeter and navigation system, and can be applied to, for example, a personal computer, a digital still camera, a cellular phone, a smartphone, a tablet terminal, a timepiece (including a smart watch), a drone, medical apparatuses (for example, an electronic thermometer, a sphygmomanometer, a blood glucose meter, an electrocardiographic apparatus, an ultrasonic diagnostic apparatus, and an electronic endoscope), various types of measurement apparatuses, meters and gauges (for example, meters and gauges for vehicles, aircrafts, and ships), a flight simulator, and the like.

### Sixth Embodiment

Next, a vehicle according to a sixth embodiment of the invention will be described.

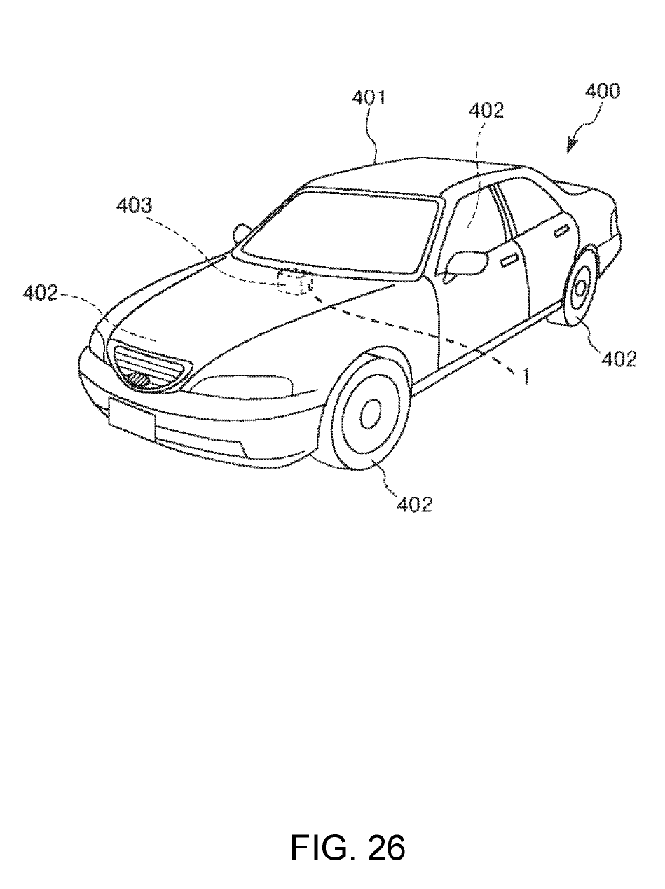

FIG. 26 is a perspective view showing a car as the vehicle according to the sixth embodiment of the invention.

As shown in FIG. 26, a car 400 as the vehicle includes a car body 401 and four wheels 402 (tires), and is configured to rotate the wheels 402 by a power source (engine) (not shown) provided in the car body 401. Further, the car 400 includes an electronic control unit (ECU) 403 mounted on the car body 401 and the pressure sensor 1 is built in this electronic control unit 403. The electronic control unit 403 ascertains the traveling state, posture, etc. of the car by detecting the acceleration, inclination, etc. of the car body 401 by the pressure sensor 1, and therefore can accurately control the wheels 402 or the like. According to this, the car 400 can safely and stably travel. The pressure sensor 1 may also be mounted on a navigation system or the like provided in the car 400.

Such a car 400 as one example of the vehicle includes the pressure sensor 1. Therefore, the car 400 can receive the effect of the pressure sensor 1 described above and can exhibit high reliability.

Hereinabove, the pressure sensor, the production method for a pressure sensor, the pressure sensor module, the electronic apparatus, and the vehicle according to the invention have been described based on the respective embodiments shown in the drawings, however, the invention is not limited thereto, and the configuration of each section can be replaced with an arbitrary configuration having the same function. Further, another arbitrary component or step may be added, and also the respective embodiments may be appropriately combined with each other.

The entire disclosure of Japanese Patent Application No. 2017-048847, filed Mar. 14, 2017 is expressly incorporated by reference herein.

What is claimed is:

1. A pressure sensor, comprising:
a substrate which has a diaphragm that is flexurally deformed by receiving a pressure;
a side wall section which is placed on one surface side of the substrate and surrounds the diaphragm in a plan view; and
a sealing layer which is placed so as to face the diaphragm through a space and seals the space, wherein
the sealing layer includes
a first silicon layer which has a through-hole facing the space,
a silicon oxide layer which is located on the opposite side to the space with respect to the first silicon layer and seals the through-hole, and
a second silicon layer which is located on the opposite side to the space with respect to the silicon oxide layer.

2. The pressure sensor according to claim 1, wherein the transverse cross-sectional area of the through-hole gradually decreases from the space side to the silicon oxide layer side.

3. The pressure sensor according to claim 2, wherein the through-hole has a portion in which the changing ratio of the transverse cross-sectional area gradually decreases from the space side to the silicon oxide layer side.

4. The pressure sensor according to claim 1, wherein the first silicon layer is placed so as to surround the opening of the through-hole, and has a protrusion portion which protrudes to the space side.

5. The pressure sensor according to claim 1, wherein the silicon oxide layer is sealed from the outside by being covered with the second silicon layer.

6. The pressure sensor according to claim 1, wherein the first silicon layer is thicker than the second silicon layer and the silicon oxide layer.

7. The pressure sensor according to claim 1, wherein the substrate contains silicon.

8. A pressure sensor module, comprising:
the pressure sensor according to claim 1; and
a package which houses the pressure sensor.

9. An electronic apparatus, comprising the pressure sensor according to claim 1.

10. A vehicle, comprising the pressure sensor according to claim 1.
